(19) United States
(12) Patent Application Publication
(10) Pub. No.: US 2023/0044064 A1
(43) Pub. Date: Feb. 9, 2023

(54) SHOWERHEAD WITH FACEPLATE HAVING INTERNAL CONTOURS

(71) Applicant: Lam Research Corporation, Fremont, CA (US)

(72) Inventors: Bin Luo, Beaverton, OR (US); Andrew Geier Melton, Portland, OR (US); Stephen Topping, Portland, OR (US); John Michael Wiltse, Lake Oswego, OR (US)

(21) Appl. No.: 17/758,341

(22) PCT Filed: Dec. 10, 2020
(86) PCT No.: PCT/US2020/064372

§ 371 Date: Jul. 1, 2022

Related U.S. Application Data
(60) Provisional application No. 62/957,657, filed on Jan. 6, 2020.

(51) Int. Cl. C23C 16/455

(52) U.S. Cl. CPC C23C 16/45565; C23C 16/45536

(57) ABSTRACT

Showerheads for semiconductor processing equipment are disclosed that include various features designed to reduce nonuniformity and adjust deposited film profiles.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools often include components designed to distribute process gases in a relatively even manner across a semiconductor substrate or wafer. Such components are commonly referred to in the industry as “showerheads.” Showerheads typically include a faceplate that fronts a semiconductor processing volume in which semiconductor substrates or wafers may be processed. The faceplate may include a plurality of gas distribution ports that allow gas in a plenum volume of the showerhead to flow through the faceplate and into a reaction space between the substrate and the faceplate (or between a wafer support supporting the wafer and the faceplate).

### SUMMARY

In one embodiment, a showerhead may be provided. The showerhead may include a faceplate having a front surface, a back surface, and a plurality of through-holes extending through the faceplate from the front surface to the back surface, a gas inlet, a plenum volume fluidically connected to the gas inlet within the showerhead and at least partially defined by the back surface. The back surface includes a nonplanar region that extends around a center axis of the faceplate, has an outer boundary and an inner boundary that are offset from each other along the center axis by a first distance, the outer boundary is closer to the gas inlet in a direction parallel to the center axis than the inner boundary, and the outer boundary is offset radially outwards from the inner boundary, and has a nonplanar surface that spans between the inner boundary and the outer boundary.

In some embodiments, the back surface may further include a circular planar region that is perpendicular to the center axis and has an outer circumferential edge defined by the inner boundary of the nonplanar region.

In some embodiments, the nonplanar surface may be a surface of revolution that is defined by a linear profile rotated about the center axis, extends between the inner boundary and the outer boundary, and is oriented at an oblique angle to the center axis.

In some embodiments, the nonplanar surface may be a conical frustum surface.

In some embodiments, the nonplanar surface may be a conical surface.

In some embodiments, the nonplanar surface may be a surface of revolution defined by a nonlinear profile rotated about the center axis and extending between the inner boundary and the outer boundary.

In some embodiments, one or more first through-holes of the plurality of through-holes may extend from the nonplanar region to the front surface, and each one or more through-hole may have a first length, one or more second through-holes of the plurality of through-holes may extend from the nonplanar region to the front surface and may be arranged farther from the center axis in a direction parallel to the center axis than the one or more first through-holes, and the one or more second through-holes each may have a second length that is longer than the first length of the one or more first through-holes.

In some embodiments, each through-hole may form an edge with the front surface, and each edge may have a radius.

In some such embodiments, the radius of each edge and the diameter of each through-hole may be substantially the same.

In some such embodiments, each through-hole may have a diameter of between about 0.01 and 0.03 inches.

In some such embodiments, the radius may be formed by electropolishing.

In some such embodiments, the radius may be formed by machining and electropolishing.

In some embodiments, the through-holes may be arranged in in a plurality of hexagonal patterns, each hexagonal pattern may have six exterior holes arranged around a center hole, and the six exterior holes may be equally spaced from each other and equally spaced from the center hole.

In some such embodiments, the distance between the six exterior holes and the center hole of each hexagonal pattern may be between about 0.1 and 0.4 inches.

In some embodiments, the outer boundary may be larger in diameter than a semiconductor substrate diameter.

In some such embodiments, the outer boundary may have a diameter between 7.5 inches and 13 inches.

In some embodiments, the first distance may be between 0.01 inches and 0.075 inches.

In some embodiments, the inner boundary may have a diameter of between about 0 inches and 8.5 inches.

In some embodiments, the showerhead may further include a back plate having the gas inlet and a first surface, and the plenum volume may be further defined by the first surface.

In some embodiments, the showerhead may further include a baffle plate having a baffle plate outer diameter and positioned within the plenum volume.

In some such embodiments, the baffle plate outer diameter and a diameter of the inner boundary may be substantially the same.

In one embodiment, a faceplate for use in a processing chamber of a semiconductor processing apparatus may be provided. The faceplate may include a front surface, a back surface including a center point and a nonplanar region, and the nonplanar region may extend around a center axis of the faceplate, may have an outer boundary and an inner boundary that are offset from each other along the center axis by a first distance, the inner boundary is closer to the center point in a direction parallel to the center axis than the outer boundary, and the outer boundary is offset radially outwards from the inner boundary, and may have a nonplanar surface that spans between the inner boundary and the outer boundary. The faceplate may also include a plurality of through-holes that extend through the faceplate from the front surface to the back surface, wherein each through-hole forms an edge with the front surface and the edge has a radius.

In some embodiments, the nonplanar surface may be a surface of revolution that is defined by a linear profile rotated about the center axis, extends between the inner boundary and the outer boundary, and is oriented at an oblique angle to the center axis.

In some embodiments, the nonplanar region may be a conical frustum surface, and the back surface may further include a circular planar region that is perpendicular to the center axis and has an outer circumferential edge defined by the inner boundary of the nonplanar region.

In some embodiments, the nonplanar region may be a conical surface.

In some embodiments, the nonplanar surface may be a surface of revolution defined by a nonlinear profile rotated about the center axis and extending between the inner boundary and the outer boundary.

In one embodiment, a method may be provided. The method may include fabricating a showerhead and the showerhead includes a faceplate having a front surface, a back surface, and a plurality of through-holes extending through the faceplate from the front surface to the back surface, a gas inlet, a plenum volume fluidically connected to the gas inlet within the showerhead and at least partially defined the back surface. The back surface may include a nonplanar region that extends around a center axis of the faceplate, has an outer boundary and an inner boundary that are offset from each other along the center axis by a first distance, the outer boundary is closer to the gas inlet in a direction parallel to the center axis than the inner boundary, and the outer boundary is offset radially outwards from the inner boundary, and has a nonplanar surface that spans between the inner boundary and the outer boundary.

In some embodiments, the back surface may further include a circular planar region that is perpendicular to the center axis and has an outer circumferential edge defined by the inner boundary of the nonplanar region.

In some embodiments, the nonplanar surface may be a surface of revolution that is defined by a linear profile rotated about the center axis, extends between the inner boundary and the outer boundary, and is oriented at an oblique angle to the center axis.

In some embodiments, the nonplanar surface may be a conical frustum surface.

In some embodiments, the nonplanar surface may be a conical surface.

In some embodiments, the nonplanar surface may be a surface of revolution defined by a nonlinear profile rotated about the center axis and extending between the inner boundary and the outer boundary.

In some embodiments, one or more first through-holes of the plurality of through-holes may extend from the nonplanar region to the front surface, and each one or more through-hole may have a first length, one or more second through-holes of the plurality of through-holes may extend from the nonplanar region to the front surface and may be arranged farther from the center axis in a direction parallel to the center axis than the one or more first through-holes, and the one or more second through-holes may each have a second length that is longer than the first length of the one or more first through-holes.

In some embodiments, each through-hole may form an edge with the front surface, and each edge may have a radius.

In some such embodiments, the radius of each edge and the diameter of each through-hole may be substantially the same.

In some such embodiments, each through-hole may have a diameter of between about 0.01 and 0.03 inches.

In some such embodiments, the radius may be formed by electropolishing.

In some such embodiments, the radius may be formed by machining and electropolishing.

In some embodiments, the through-holes may be arranged in in a plurality of hexagonal patterns, each hexagonal pattern may have six exterior holes arranged around a center hole, and the six exterior holes are equally spaced from each adjacent through-hole and equally spaced from the center hole.

In some such embodiments, the distance between each adjacent exterior hole, and each exterior hole and the center hole of each hexagonal pattern is between about 0.1 and 0.4 inches.

In some embodiments, the outer boundary ay be larger in diameter than a semiconductor substrate diameter.

In some such embodiments, the outer boundary may have a diameter greater than 11 inches.

In some embodiments, the first distance may be between 0.01 inches and 0.075 inches.

In some embodiments, the inner boundary may have a diameter of between about 1.25 and 3.5 inches.

In some embodiments, the showerhead may further include a back plate having the gas inlet and a first surface, wherein the plenum volume is further defined by the first surface.

In some embodiments, the showerhead may further include a baffle plate having a baffle plate outer diameter and positioned within the plenum volume.

In some such embodiments, the baffle plate outer diameter and a diameter of the inner boundary may be substantially the same.

### BRIEF DESCRIPTION OF THE DRAWINGS

FIG. 1A depicts an isometric view of an example showerhead according to disclosed embodiments.

FIG. 1B depicts a cross-sectional off-angle view of the showerhead of FIG. 1A.

FIG. 1C is a side view of the showerhead cross-section of FIG. 1B.

FIGS. 2A and 2B depict an off-angle view of a simplified faceplate with a nonplanar back surface.

FIG. 2C depicts a cross-sectional off-angle view of the faceplate of FIG. 2A.

FIG. 2D depicts a side view of a cross-sectional slice of the faceplate of FIG. 2C.

FIG. 3 depicts an illustrative conical frustum surface.

FIG. 4A shows a cross-sectional slice of faceplate with a conical-shaped nonplanar region and FIG. 4B shows a cross-sectional slice of faceplate with a nonconical shaped nonplanar region.

FIG. 5 depicts a cross-sectional slice of half the faceplate of FIG. 1C.

FIG. 6 depicts thicknesses of a deposited material on five wafers in a first deposition experiment.

FIG. 7 depicts thicknesses of a deposited material on two wafers in a second deposition experiment.

FIG. 8 depicts a first through-hole pattern of the faceplate.

FIG. 9A depicts measured nonuniformity of a deposited material on a first wafer using a conventional showerhead in a third deposition experiment and FIG. 9B depicts measured nonuniformity of the deposited material on the second wafer in the third deposition experiment.

FIG. 10 depicts a magnified, partial cross-sectional view of two example through-holes of the faceplate.

FIG. 11 depicts a schematic of a substrate processing apparatus for depositing films on semiconductor substrates using any number of processes.

FIG. 12 shows an example multi-station substrate processing apparatus.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

In this application, the terms “semiconductor wafer,” “wafer,” “substrate,” “wafer substrate,” and the like are used interchangeably. A wafer or substrate used in the semiconductor device industry typically has a diameter of 200 mm, 300 mm, or 450 mm, but may also be non-circular and of other dimensions. In addition to semiconductor wafers, other work pieces that may take advantage of this invention include various articles such as printed circuit boards, magnetic recording media, magnetic recording sensors, mirrors, optical elements, micro-mechanical devices and the like.

Several conventions may have been adopted in some of the drawings and discussions in this disclosure. For example, reference is made at various points to “volumes,” e.g., “plenum volumes.” These volumes may be generally indicated in various Figures, but it is understood that the Figures and the accompanying numerical identifiers represent an approximation of such volumes, and that the actual volumes may extend, for example, to various solid surfaces that bound the volumes. Various smaller volumes, e.g., gas inlets or other holes leading up to a boundary surface of a plenum volume, may be fluidically connected to those plenum volumes.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

It is to be understood that the use of relative terms such as “above,” “on top,” “below,” “underneath,” etc. are to be understood to refer to spatial relationships of components with respect to the orientations of those components during normal use of a showerhead or with respect to the orientation of the drawings on the page. In normal use, showerheads are typically oriented so as to distribute gases downwards towards a substrate during substrate processing operations.

It is desirable in semiconductor processing to reduce nonuniformity of deposited materials onto wafers, reduce particle generation, reduce the occurrence of unwanted hollow cathode discharge (HCD) during plasma generation, and adjust a profile of the deposited material. A semiconductor processing showerhead's features and flow characteristics within and through the showerhead can lead to some of these unwanted effects. For instance, structures within the showerhead may lead to the generation of localized nonuniformity and particle generation on the substrate near these structures, e.g., internal baffle plates and supporting structures may cause localized nonuniformity on the substrate in the area below or near the baffle plate, and structures supporting the baffle plate may cause particle generation and contamination on the substrate. The configuration of a showerhead's through-holes may also lead to nonuniformity and the occurrence of HCD.

Described herein are showerheads with various features that are configured to reduce nonuniformity of material deposited onto substrates, reduce particle contamination onto substrates, reduce the occurrence of unwanted hollow cathode discharge (HCD), and create desired film profiles across the substrate. The showerhead includes a faceplate with a front surface facing the substrate, a back surface partially defining the plenum volume of the showerhead, and through-holes extending between the two surfaces. The faceplate's back surface is a nonplanar surface configured to improve flow within and through the showerhead which, in turn, reduces nonuniformity; the geometric characteristics of the nonplanar region of the back surface may also affect the film profile such that changes to these geometric characteristics may result in different film profiles, such as a profile with a higher or a lower radial edge. The nonplanar region may have various shapes, such as a conical frustum surface, a conical surface, a concave surface, and a curved surface.

The faceplate through-holes may have characteristics and arrangements that also provide various benefits. In some embodiments, the diameter of the through-holes may be sized small enough to prevent unwanted plasma generation within each hole and to create a pressure drop between the showerhead plenum volume and the volume external to the showerhead that reduces nonuniformity across the substrate, local nonuniformity, and particle generation; this pressure drop may also work in conjunction with the nonplanar surface to create different film profiles. In some embodiments, the edge of each through-hole at the faceplate front surface may be rounded with a radius that reduces unwanted HCD.

As described in more detail below, the ability to reduce nonuniformity and affect film profiles using a faceplate having a back surface with a nonplanar region using some of the dimensions described below was a surprising result. In some instances, the dimensions of the nonplanar surface region's depth would normally fall within the normal or default tolerance ranges. In some embodiments, the nonplanar region includes an outer boundary and an inner boundary offset from each other along a center axis of the faceplate by a small offset distance that is not achievable with typical manufacturing techniques because the offset distance may be within or close to typical tolerance limits. Similarly, the offset distances may be a very small percentage of the overall thickness of the faceplate in the region that would be positioned over the semiconductor wafer during processing, such as between around 2.5% of the nominal thickness of the faceplate, for example. Some of the offset distances described herein are sufficiently small that they would fall within the normal or default tolerance ranges of some showerheads, i.e., the presence or absence of such a profile would both be considered “within tolerance” for such showerheads. Nevertheless, the small offset distances of the nonplanar region provided herein had surprising and significant effects of reducing nonuniformity and changing the film profile.

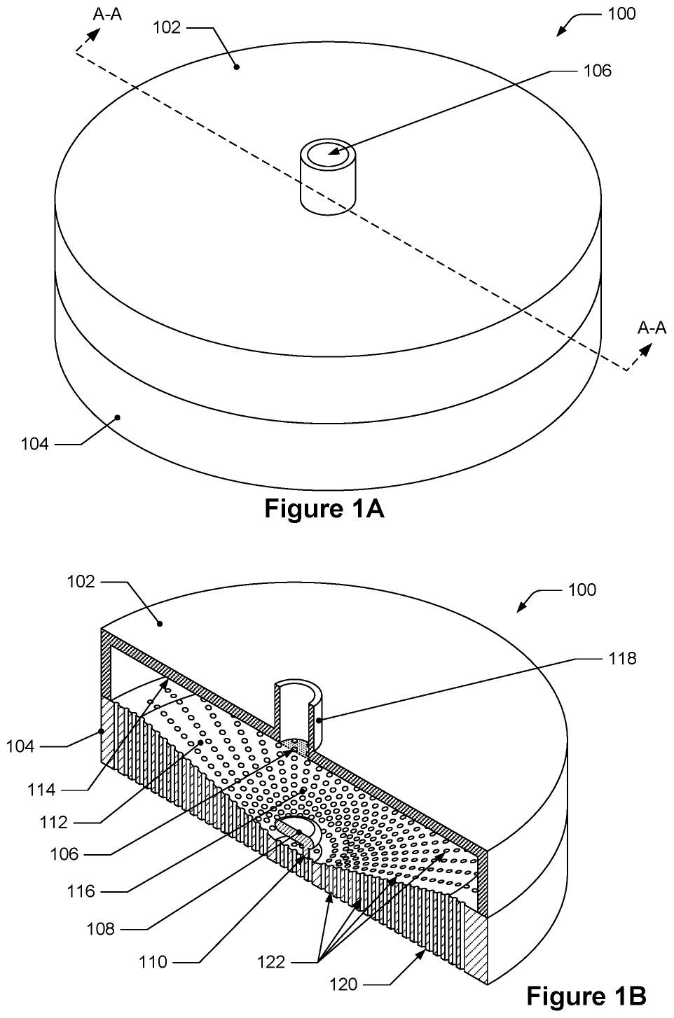

FIG. 1A depicts an isometric view of an example showerhead according to disclosed embodiments and FIG. 1B depicts a cross-sectional off-angle view of the showerhead of FIG. 1A. The cross-sectional view of FIG. 1B is taken along section line A-A in FIG. 1A. The example showerhead in all of the Figures herein are illustrative schematics intended to convey the concepts described herein; they are not intended to be an exact representation and they are not to scale. Showerhead 100 includes a back plate 102, a faceplate 104, and a gas inlet 106. The gas inlet 106 is considered part of the showerhead 100 itself and may be, for example, at the end of a stem of the showerhead 100.

In the cross-sectional view of FIG. 1B, internal features of the showerhead 100 are seen including a baffle plate 108 (which, in some implementations, may be omitted), a post 110 supporting the baffle plate 108 (which may also be omitted if the baffle plate 108 is not used), a back surface 112 of the faceplate 104, and a first surface 114 of the back plate 102. The back surface 112 of the faceplate 104 and the first surface 114 of the back plate 102 together partially define a plenum volume 116 within the showerhead 100. In some embodiments, such as depicted in FIG. 1B, the baffle plate 108 may be positioned within the plenum volume 116. The back plate 102 and the faceplate 104 may be positioned opposite one another within the showerhead 100 such that the first surface 114 of the back plate 102 and the nonplanar back surface 112 of the faceplate 104 face each other. The faceplate 104 also includes a plurality of through-holes 122, some of which are identified, that extend from the back surface 112 to the front surface 120 (the front surface 120 is identified but not fully visible in FIG. 1B); these through-holes 122 fluidically connect the plenum volume 116 with the environment outside the showerhead 100, such as where the substrate is positioned during semiconductor processing operations.

The gas inlet 106 is considered a part of the showerhead 100 and may also partially define the plenum volume 116; as depicted in FIG. 1B, the gas inlet 106 is a port in the back plate 102 identified with light shading. As stated herein, the gas inlet 106 may be fluidically connected to other fluid conduit hardware, such as piping, valves, and/or the stem of a chandelier-style showerhead. In FIGS. 1A and 1B, the gas inlet 106 is fluidically connected to fluid conduit 118, which may be, for example, the stem of the showerhead. In some embodiments, the baffle plate 108 may be centered under the gas inlet 106 such that the center axis of the baffle plate 108 is collinear with the center axis of the gas inlet 106.

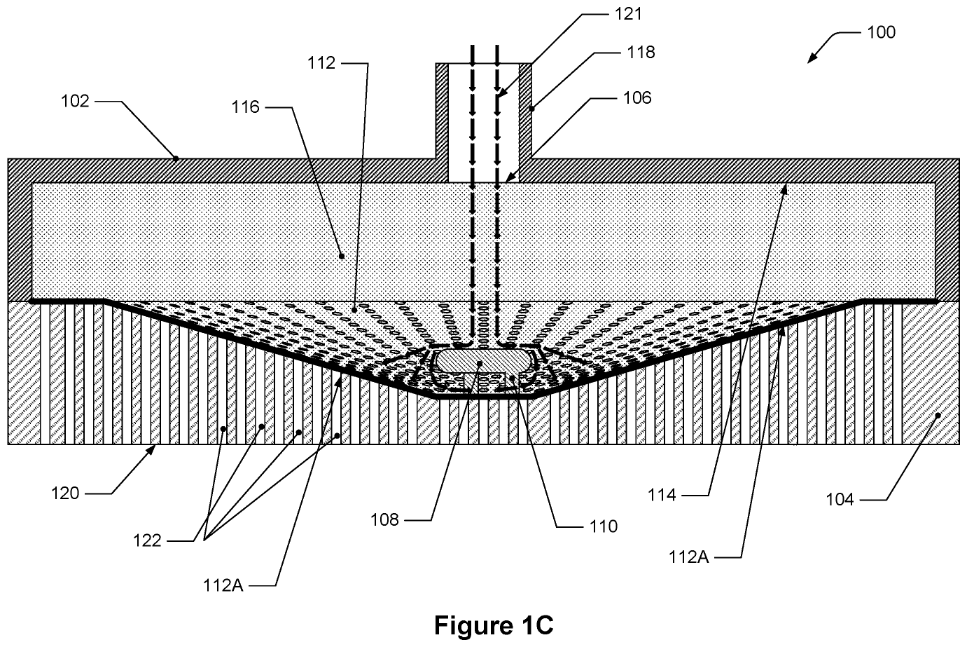

FIG. 1C is a side view of the showerhead cross-section of FIG. 1B. Here, some of the features identified above are seen, including the first surface 114 of the back plate 102, as well as the front surface 120, the back surface 112, and the through-holes 122 of the faceplate 104; the plenum volume 116 is also represented with light shading. As mentioned above, the back surface 112 of the faceplate 104 is a nonplanar surface and in FIG. 1C, the cross-sectional profile 112A of the back surface 112 is depicted with a heavy solid line. Additional aspects of the nonplanar back surface 112 are illustrated in FIGS. 2A-2D.

FIGS. 2A and 2B depict off-angle views of a simplified faceplate with a nonplanar back surface, 2C depicts a cross-sectional off-angle view of the faceplate of FIG. 2A, and FIG. 2D depicts a side view of a cross-sectional slice of the faceplate of FIG. 2C. In these figures, the faceplate 104 of FIGS. 1A-1C is shown except that for illustration purposes, the through-holes and baffle plate have been removed; it should be understood that in all embodiments, the faceplate 104 includes through-holes. In FIG. 2A, the faceplate 104 includes a center axis 124 and the nonplanar back surface 112 which is highlighted with light shading. In FIG. 2B, the nonplanar back surface 112 includes a nonplanar region 126 that extends around the center axis 124 and is highlighted with dark shading. The nonplanar region 126 has an outer boundary 128 that extends around the center axis 124 and forms the outermost circumferential boundary of this surface region with respect to the center axis 124, an inner boundary 130 that extends around the center axis 124 and forms the innermost circumferential boundary of this surface region with respect to the center axis 124, and a nonplanar surface that extends between the inner boundary 130 and the outer boundary 128; this nonplanar surface is the shaded section also identified as 126. The inner boundary 130 and the outer boundary 128 in FIGS. 2A and 2B are illustrated with heavy weight lines.

In some embodiments, as depicted in FIG. 2B, the nonplanar back surface 112 may also include a center region 132 that may be, in some instances, planar. The center region 132 in FIG. 2B is a planar, circular surface that is perpendicular to the center axis 124 and has an outer boundary that is formed by the inner boundary 130 of the nonplanar region 126. In some instances, the meeting of these boundaries may have a radius or curve in order to smoothly transition between the nonplanar surface of the nonplanar region 126 and the planar center region 132.

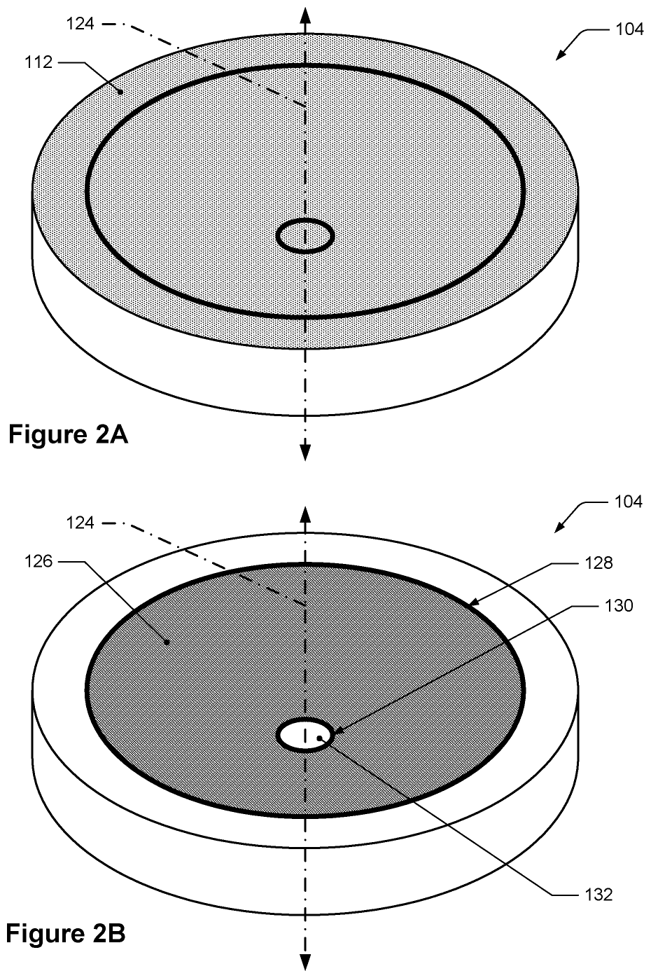

The nonplanar region 126 of the faceplate 104 may have various geometries and arrangements, such as a conical, conical frustum, or curved shape. The nonplanar region 126 shown in FIGS. 1A-2D may be considered a conical frustum surface. A conical frustum surface, as the term is used herein, is a right circular or conical surface without the pointed end; a plane perpendicular to axis of rotation of the conical frustum slices or cuts off the point. The conical surfaces described herein may also be considered right frustrum surfaces. FIG. 3 depicts an illustrative conical frustum surface. As can be seen, the conical frustum surface, S, is defined by a first circumference C₁ having a first radius, R₁ and a second circumference C₂ having a second radius R₂ that is larger than the first radius R₁; the two circumferences are offset from each other by a height H along a center axis that is perpendicular to the planes defined by both circumferences. The length, L, of the conical frustum surface spans between the first and second circumferences C₁ and C₂. The conical frustum surface is offset from the center axis by a first angle θ₁.

Referring to FIG. 2C, which depicts a cross-sectional off-angle view of the faceplate of FIG. 2B, the shape of the nonplanar region 126 is further explained. Here, the nonplanar surface 126 extends between the first circumference, which is the inner boundary 130, and the second circumference, which is the outer boundary 128, and has a length 134. The nonplanar region 126 has a height 136 which is defined by the distance that the outer boundary 128 and the inner boundary 130 are offset from each other along the center axis 124. It may also be considered that the outer boundary 128 and the inner boundary 130 are offset from each other in a direction parallel to the center axis 124 by the height 136 amount; this height may also be referred to herein as a depth of the nonplanar region.

The features of the faceplate are further illustrated in the cross-sectional side view of FIG. 2D. This Figure shows a cross-sectional slice of the faceplate taken in a plane along the center axis; for illustration purposes, the cross-hatching has been omitted. Here, the side profile of the nonplanar region is visible and highlighted with heavy weight lines. The nonplanar region profile includes a first section 138A and a second section 138B that have the same length 134. The inner boundary 130 and the outer boundary 128 are also visible and represented as points; the first section 138A and the second section 138B each span between the outer boundary 128 and the inner boundary 130. As stated above and seen in FIG. 2D, the outer boundary 128 and the inner boundary 130 are offset from each other along, or in a direction parallel to, the center axis 124 by the height 136 when viewed perpendicular to the center axis 124. In some embodiments, the outer boundary 128 and the inner boundary 130 may also be considered offset from each other such that, when viewed perpendicular to the center axis 124, the inner boundary 130 is closer to the front surface 120 than the outer boundary 128 in a direction parallel to, or along, the center axis 124.

When viewed perpendicular or parallel to the center axis, the inner boundary 130 and the outer boundary 128 are also offset from each other. In some embodiments like that in FIG. 2D, the inner boundary 130 is offset from the center axis 124 in a direction perpendicular to the center axis 124 by a first radial distance 140, and the outer boundary is offset from the center axis 124 in the direction perpendicular to the center axis 124 by a second radial distance 142 that is longer than the first radial distance 140. The outer boundary may also be considered offset from the inner boundary 130 in the direction perpendicular to the center axis 124 by a third radial distance 144. The first section 138A and the second section 138B may be angled away from the center axis by a first angle θ₁ that is oblique; it is depicted as an acute angle in this Figure. This first angle θ₁ decreases as the height 136 (first distance) increases.

In some embodiments, the nonplanar region may be considered defined by a profile that extends between the inner boundary and the outer boundary and that is rotated about the center axis. In FIG. 2D, the profile of the nonplanar region 126 may be considered the first section 138A (or the second section 138) which is a linear profile in this embodiment. As stated above, this linear profile is angled away from the center axis by a first angle θ₁ that is oblique. This linear profile, the first section 138A, is swept around all of the center axis 124 as represented by the curved double arrow. In some embodiments, like in FIG. 2D, the linear profile is offset from the center axis 124 by the distance 140 in a radial direction. The rotation around the center axis 124 of the linear profile creates the nonplanar region.

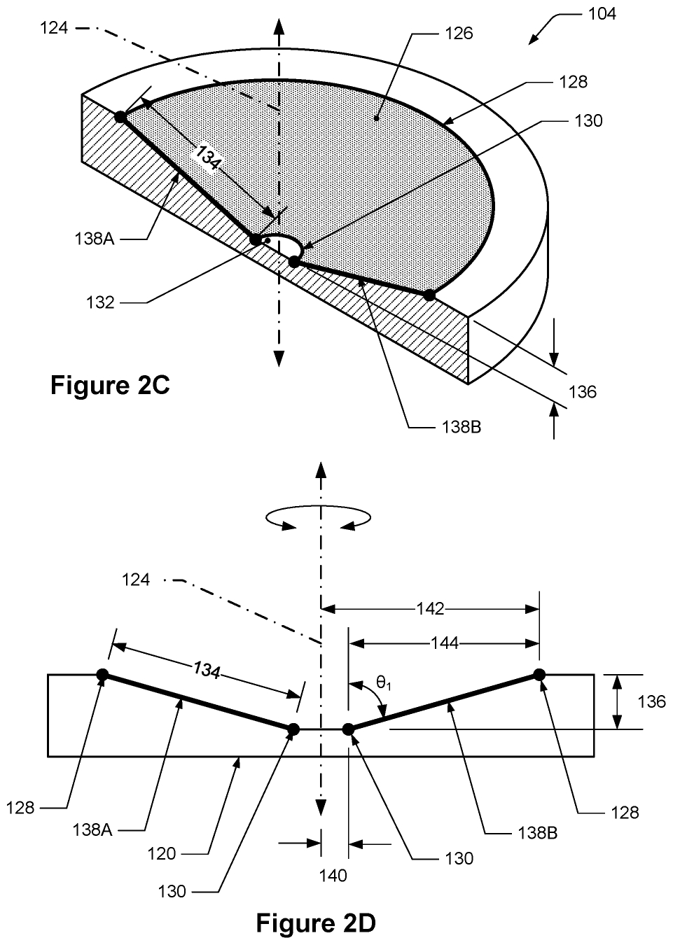

In some embodiments, the nonplanar region of the faceplate's nonplanar back surface may have other shapes and geometries as illustrated in FIGS. 4A and 4B, which depict various examples of faceplate cross-sectional slices. For example, the nonplanar region of the nonplanar back surface may have a conical shape, i.e., a cone with a point at the center as seen in FIG. 4A. Here, the nonplanar region includes an outer boundary 428 and an inner boundary 430 which may be a single point as shown, and the nonplanar surface spans between this point 430 and the outer boundary 428. This illustrated side profile shows that the first section 438A and the second section 438B share the common inner point 430. The nonplanar surface has the length 434 that spans from the inner boundary, or point, 430 to the outer boundary 428; the outer boundary 428 and the inner boundary 430 are offset from each other along, or in a direction parallel to, the center axis 424 by the height 436. The outer boundary is also offset from the center axis 424 in the direction perpendicular to the center axis 424 by a second radial distance 442. The inner boundary 430 is positioned on the center axis 424; is not offset from the center axis 424. The first section 438A and the second section 438B (which are two sections of the same nonplanar region) may also be angled away from the center axis by a first angle θ₁ that is oblique; it is depicted as an acute angle in this Figure. Similar to above, the conical nonplanar region in FIG. 4A may be defined by a linear profile, section 438A, that is rotated around the center axis 424.

In some embodiments, the nonplanar region may have a shape formed by a nonlinear profile rotated about the center axis. FIG. 4B shows a cross-sectional slice of faceplate with a nonplanar region having a nonlinear cross-sectional profile. Again, the nonplanar region includes the outer boundary 428 and the inner boundary 430 that are offset from each other and from the center axis 424. Here, the nonplanar surface that spans between the outer boundary 428 and the inner boundary 430 has a nonlinear, e.g., curved, profile. This side profile shows that the first section 438A and the second section 438B are nonlinear and in this embodiment, are curved. The outer boundary 428 and the inner boundary 430 are again offset from each other along, or in a direction parallel to, the center axis 424 by the height 436. Similar to FIG. 2D, in FIG. 4B, the inner boundary 430 is offset from the center axis 424 in a direction perpendicular to the center axis 424 by a first radial distance 440, and the outer boundary is offset from the center axis 424 in the direction perpendicular to the center axis 424 by a second radial distance 442 that is longer than the first radial distance 440. In some other embodiments, the inner boundary of FIG. 4B may be a single point on the center axis 424 as shown in FIG. 4A.

The curvature of the nonlinear profile may have a constant curvature, may have two or more curves, and may also be defined by various nonlinear equations that may vary the curvature as the radial distance from the center axis 424 changes. For instance, the curvature may be defined by a polynomial function, such as a quadratic, a cubic, or a quartic function.

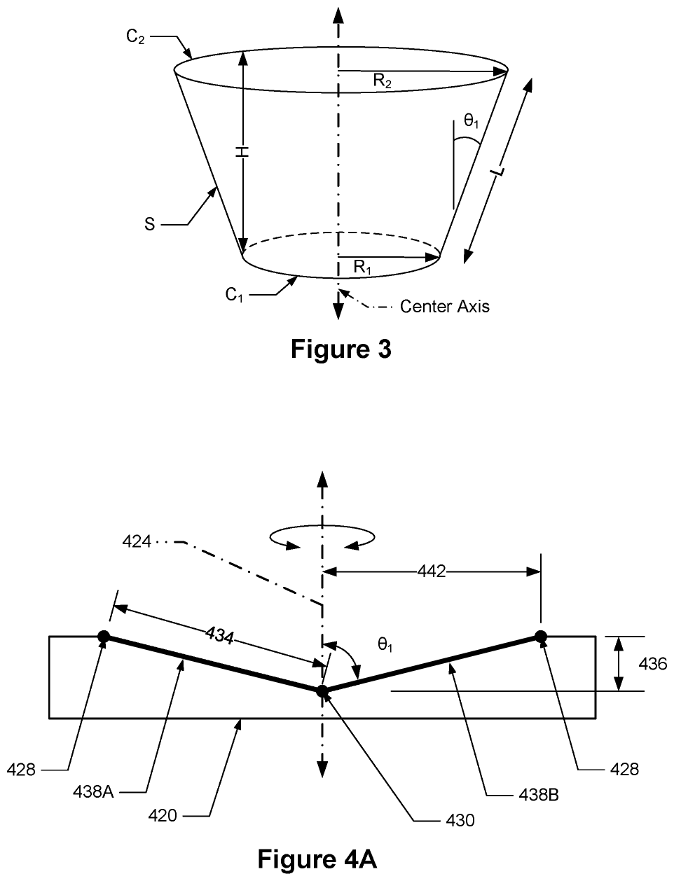

In some embodiments, it may be considered that the nonplanar region of the faceplate's nonplanar surface is configured such that the through-holes have different, such as longer, for example, lengths as the radial distance from the center axis increases; these varying lengths reduce nonuniformity and allow for the film profile to be adjusted. FIG. 5 depicts a cross-sectional slice of half the faceplate of FIG. 1C. Here, the center axis 124, half of the center region 132, the second section 138B of the nonplanar region, the inner boundary 130, and the outer boundary 128 are seen. This Figure also includes a plurality of through-holes 122, with a section of these through-holes having different lengths from each other. In the center region, the through-holes 122 have equal lengths and along the second section 138B, the through-holes have increasing lengths as the radial distance increases from the center axis 124. For example, through-hole 122A is radially closer to the center axis 124 than through-hole 122B. Through-hole 122A is offset by a first radial distance 544A from the center axis 124 and has a first length 546A, while through hole 122B is offset by a second radial distance 544B from the center axis 124 that is larger than the first radial distance 544A, and through hole 122B has a second length 546B that is longer than the first length 546A. Similarly, through-hole 122C has a third radial distance 544C that is longer than the first and second radial distances 544A and 544B, respectively, and has a third length 546C that is longer than the first and second lengths 146A and 546B, respectively.

As illustrated in FIG. 5, due to the angled profile of the nonplanar region with respect to the center axis, the through-holes that extend through the nonplanar region have increasing lengths as their radial distance from the center axis increases. Similarly, the shapes of the nonplanar regions illustrated in FIGS. 4A and 4B also result in the same effect of having through-holes with variable lengths that increase as the radial distance from the center axis increases. As described herein, these variable and increasing lengths reduce nonuniformity and allow for the adjustment of a film profile.

The dimensions of the nonplanar back surface and the through-holes of the faceplates described herein result in numerous and unexpected advantages including reducing nonuniformity and allowing for the adjusting a film profile on the wafer. For example, in some embodiments, the depth 136 of the nonplanar region 126 of the faceplate 104 may range between about 0.01 inches and 0.075 inches, including 0.01 inches, 0.011 inches, 0.012 inches, 0.013 inches, 0.015 inches, 0.017 inches, 0.02 inches, 0.025 inches, 0.035 inches, 0.05 inches, 0.055 inches, 0.065 inches, and 0.075 inches, for instance. Varying the depth of the nonplanar region changed the overall through-hole lengths. These changes adjusted the flow characteristics through the faceplate and led to nonuniformity reductions and film profile adjustability.

In some implementations, the inner diameter 130 of the nonplanar region 126 may have a diameter of between about 0 inches and 8.5 inches, including 2.1, 2.3, 3, 4, 5, 6, 7, 8, and 8.5 inches. In some embodiments, the inner diameter 123 may be equal to or substantially equal to (e.g., within about ±5%) the outer diameter of the baffle plate; these diameters may not be exactly the same and may be considered substantially the same because of, for instance, manufacturing tolerances and imperfections. In some implementations, the outer diameter 128 of the nonplanar region 126 may also be between 7.5 inches and 13 inches, for example, including 7.5, 8, 8.5, 9, 12 12.3, 12.5, 12.75, and 13 inches. In some instances, the outer diameter 128 may be sized larger than the outer diameter of a substrate which may be at least 300 millimeters. Accordingly, in some implementations, the nonplanar region's depth may be between about 0.006% and 0.052% of its outer diameter, e.g., between 12 inches and 12.5 inches. To give a sense of perspective, the internal, plenum-defining surface features of typical showerheads are generally machined to tolerances of about ±0.005 inches—at such tolerances, features such as some of the non-planar regions discussed above may see shifts in size and aspect ratio that they lose their efficacy, for example, a flat back surface would technically be within ±0.005 inches of a non-planar region having a depth of 0.010 inches, in which case the non-planar region would effectively vanish. Thus, due to the potentially small depth of such non-planar regions, the back surface of the faceplate having the non-planar region may be machined to a much tighter tolerance than is typically used for showerhead features, e.g., ±0.001 inches or ±0.0005 inches.

Although making the back surface of the faceplate nonplanar, as compared to many typical showerheads that use a planar back surface, resulted in numerous benefits including reduced nonuniformity, the present inventors further discovered that, in some implementations, when the internal showerhead pressure was increased to higher pressures, such as at least 5 Torr, and between 5 Torr and 25 Torr, utilizing a nonplanar surface with a relatively small depth, e.g., that is less than or close to typical machining tolerances, and making adjustments thereto resulted in numerous advantages including substantial adjustability and reductions of nonuniformity.

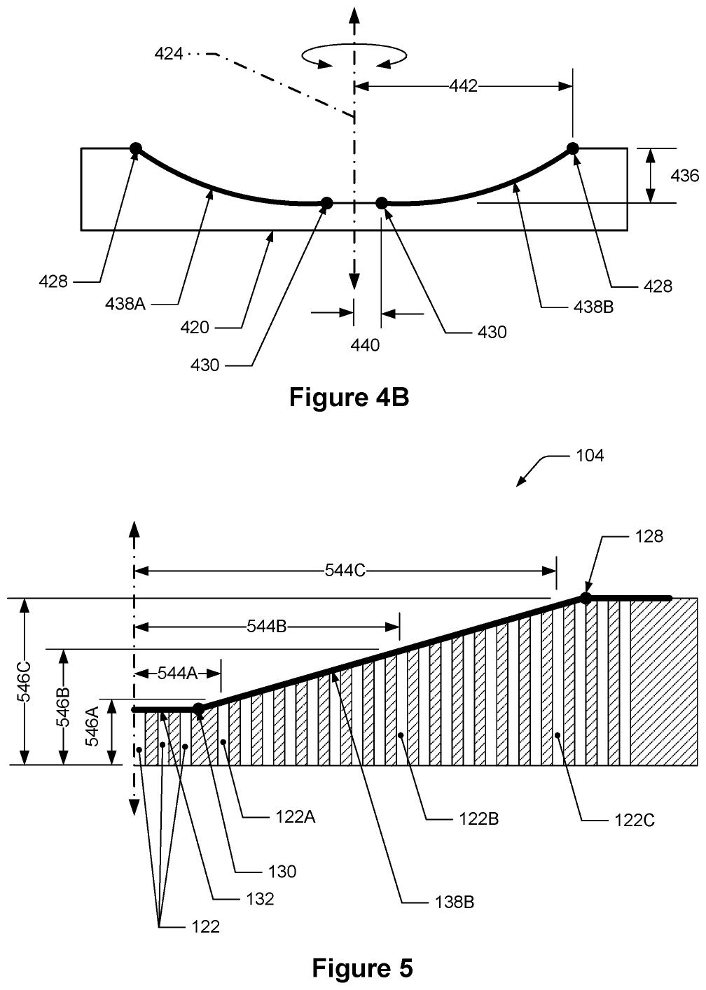

For example, in one experiment, five different depositions were performed under the same conditions except that the showerhead used in each deposition process had a faceplate with a different back surface profile than the other faceplates. FIG. 6 depicts thicknesses of a deposited material on five wafers in a first deposition experiment. In FIG. 6, the x-axis is measurement points along the substrate, with 0 being the wafer center, while the y-axis is the normalized thickness of the deposition layer. In this Figure are five sets of data; the first is for a planar back surface, the second set is for a nonplanar surface with a conical frustum surface having a first depth, the third set is for a nonplanar surface with a conical frustum surface having a second depth larger than the first depth, the fourth set is for a nonplanar surface with a conical frustum surface having a third depth larger than the second depth, and the fifth set is for a nonplanar surface with a conical frustum surface having a fourth depth larger than the fifth depth. In this Figure, the depths of the conical frustrum surface are within the range described above, 0.01 inches and 0.075 inches, including 0.01 inches, 0.011 inches, 0.012 inches, 0.013 inches, 0.015 inches, 0.017 inches, 0.02 inches, 0.025 inches, 0.035 inches, 0.05 inches, 0.055 inches, 0.065 inches, and 0.075 inches, for instance. As can be seen, under these process conditions, the second set of data using the first depth has less nonuniformity than the first set of data having the planar back surface. Also, the shallowest depth, the first depth of the second set of data, resulted in the best uniformity while the largest depth, the fourth depth, resulted in the least uniformity and in the lowest edge thickness. The second largest depth, the third depth, resulted in the second lowest edge thickness. The third, fourth, and fifth sets of data illustrate both the film profile sensitivity to different contour depths and the ability to adjust and modulate a film profile using different nonplanar back surface depths. For example, it may be desirable to adjust the film profile in order to create nonplanar or nonuniform regions on the substrate, such as a film with thicker or thinner radial edges as compared to the center of the wafer.

The present inventors found that decreasing the faceplate through-hole diameters could create the desired internal showerhead pressure by restricting flow to such an extent that the desired internal showerhead pressure could be maintained at steady state. Changing the flowrates to achieve higher pressures may have detrimental effects to the process, such as higher flow nonuniformity. Typical through-hole diameters for showerheads may be greater than at least 0.04 inches, or 0.05 inches. When the through-hole diameters were decreased to less than 0.04 inches, such as to about 0.02 inches and 0.015 inches for instance, it was found that the showerhead internal pressure increased to higher pressures, such as at least 5 Torr and including up to 25 Torr. Accordingly, in some embodiments, the through-hole diameters may range from about 0.01 inches to 0.03 inches, including about 0.01, 0.015, 0.018, 0.019, 0.02, 0.025, 0.027, and 0.03 inches for example.

The pressure increase resulting from decreasing the through-hole diameters caused numerous advantageous and unexpected results. For example, the higher internal pressure of the showerhead caused the internal volume to have a plenum effect which increased the pressure uniformity which in turn increased flow sensitivity to the lengths of the faceplate's through-holes which are driven by the faceplate nonplanar region. This increased sensitivity allows for the fine tuning of the film profile by the nonplanar back surface of the faceplate and its relatively small dimensions and adjustments thereto. Again, modulating the length of the through-holes modulates the pressure drop along the faceplate and allows for film profile adjustment.

This increased pressure also reduced non-advantageous effects caused by the baffle plate. Use of the baffle plate is advantageous for numerous reasons, such as reducing internal volume to use less process gases and improving flow distribution throughout the showerhead. For example, referring back to FIG. 1C, some of the gas flow into the showerhead 100 is represented by black arrows 121 and this gas flow 121 travels through the conduit 118, to and through the gas inlet 106 into the plenum volume 116, onto the baffle plate 108, and radially outwards and under the baffle plate 106. The present inventors found that the baffle plate may cause unintended negative effects, including causing local nonuniformity that is associated with the outer edge of the baffle plate and causing particle generation which contaminates the wafer. For instance, in a second experiment, material was deposited on one wafer using a conventional showerhead with a faceplate having a planar back surface and through-holes with a 0.040 diameter and on a second wafer using a showerhead with a faceplate having a nonplanar conical frustum back surface and through-holes with 0.020 diameters.

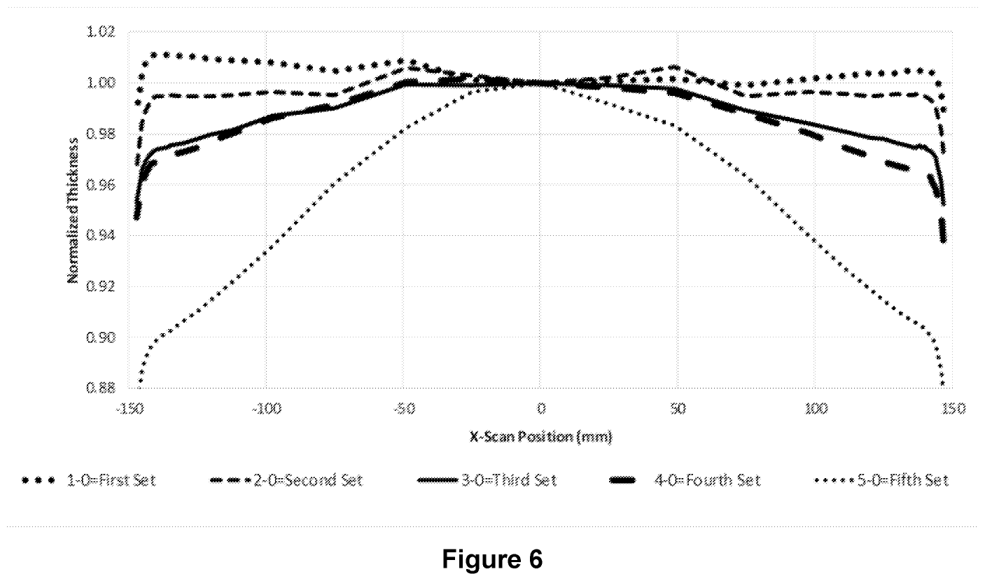

FIG. 7 depicts thicknesses of a deposited material on two wafers in the second deposition experiment. In FIG. 7, the x-axis is measurement points along the substrate, with 0 being the wafer center, while the y-axis is the normalized thickness. As can be seen in this Figure, the 0.020 diameter through-holes resulted in less nonuniformity over the entire wafer than the 0.040-inch diameter through-holes. Additionally, the 0.020 diameter through-holes reduced localized nonuniformity caused by the baffle plate. In these experiments, the showerheads include a baffle plate with an outer diameter of about 100 millimeters which positioned at about −50 mm and 50 mm from the center of the wafer; the material peaks in FIG. 7 at the −50 mm and 50 mm positions indicate nonuniformity associated with the edge of the baffle plate. The 0.020 diameter through-holes reduced this localized nonuniformity caused by the baffle plate because the reduced cross-sectional area of such through-holes generated a higher internal pressure within the plenum, which made the pressure distribution across the back surface of the faceplate more uniform and thus less susceptible to being affected by the baffle plate.

The present inventors discovered that posts supporting the baffle plate can cause particle generation and particle contamination on the wafer. Similar to above, the 0.020 diameter through-holes reduced this particle generation and contamination caused by the baffle plate posts.

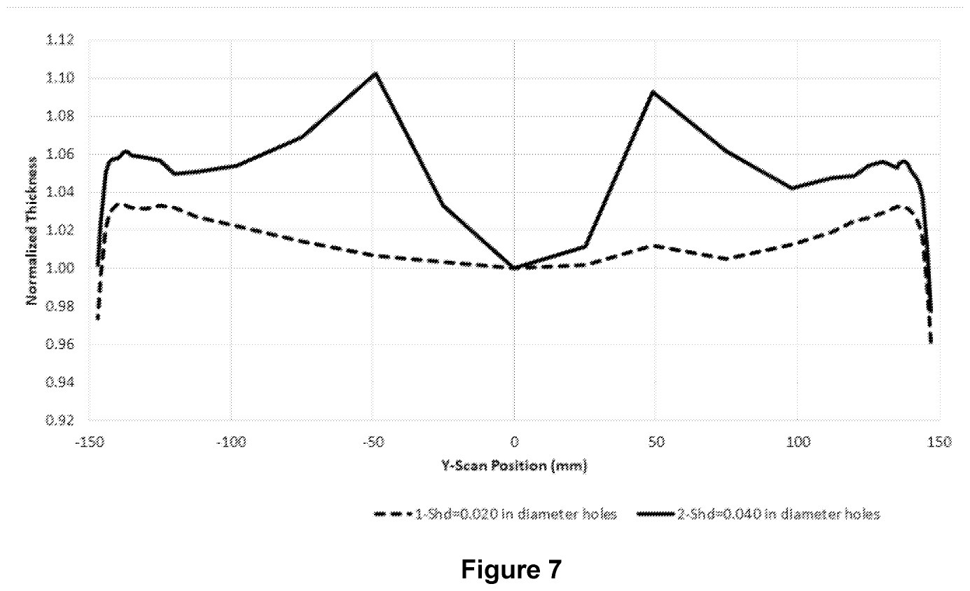

In some embodiments, the faceplate through-holes may be arranged in a pattern that also reduces nonuniformity. The pattern includes six perimeter holes arranged in a hexagonal pattern around a center hole and with all seven holes all equally spaced from each other. This pattern may be considered a hexagonal with a center hole, a hex-close-packed, a double-hex, or an equilateral triangular pattern. FIG. 8 depicts a first through-hole pattern of the faceplate. Here, six through-holes are arranged in a hexagonal shape 950 around a center through-hole 922C, and all the seven through-holes are equally spaced from the closest adjacent through-holes, as indicated by distance D1 between some of these holes. For instance, adjacent periphery through-holes 922A and 922B are equally spaced from each other by separation distance D1 and equally spaced from the center through-hole 922C by the separation distance D1. In some instances, this separation distance D1 between the through-holes may be between about 0.100 inches and 0.400 inches, including about 0.150, 0.162, 0.200, and 0.250 inches. The present inventors discovered that having a hole at the center of the faceplate (e.g., the center axis of this through-hole being substantially collinear with the faceplate center axis) and using this hexagonal with a center hole pattern for the majority of the faceplate, and in some embodiments across all of the faceplate, reduced nonuniformity as compared to a traditional hexagonal pattern that does not have a center hole.

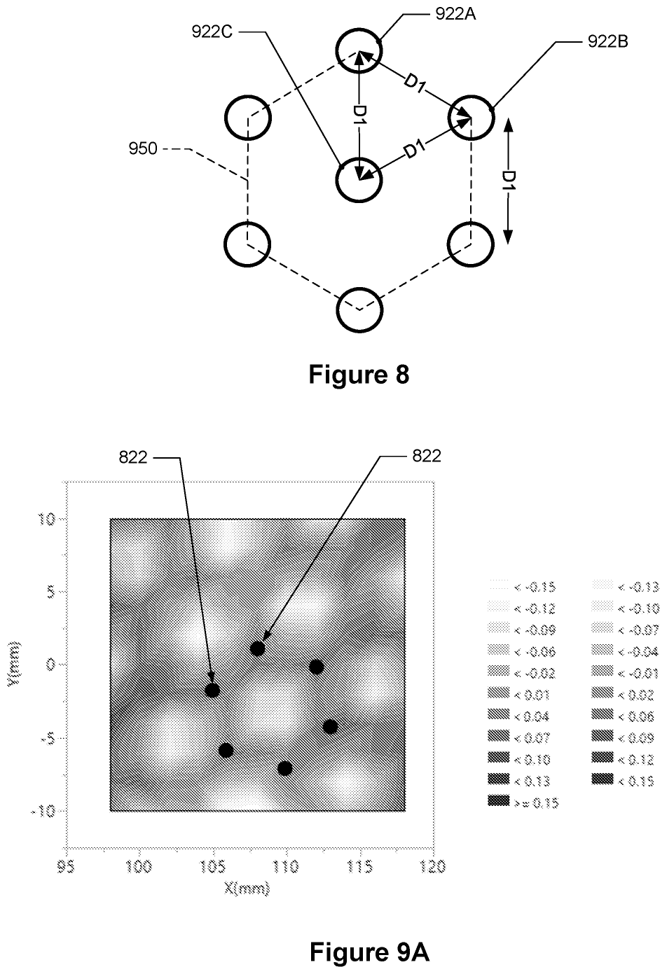

In a third experiment, material was deposited on one wafer using a conventional showerhead with a faceplate having a planar back surface and through-holes in a hexagonal pattern with 0.040 diameters, and on a second wafer using a showerhead with a faceplate having a nonplanar conical frustum back surface and through-holes in a hexagonal with a center hole pattern and with 0.020 diameters. FIG. 9A depicts measured nonuniformity of a deposited material on the first wafer using the conventional showerhead in the third deposition experiment and FIG. 9B depicts measured nonuniformity of the deposited material on the second wafer in the third deposition experiment. In these Figures, the x- and y-axes are measurement positions on the substrate, and a key to the depicted nonuniformity is on the right side of each Figure. In FIG. 9A, the six through-holes in a hexagonal pattern are also shown and as can be seen, there is nonuniformity in the center of this hexagonal pattern as represented by light shading, while there is different material thickness around the periphery of this pattern as represented by the dark shading. In FIG. 9B, the hexagonal with a center hole pattern is shown and the nonuniformity is reduced as represented by the absence of the lighter shading and a more consistently darker shading around and within this pattern indicating the deposited material is more uniform with this pattern. It will be understood that in both experiments, additional hexagonal patterns of holes were included as well, although only a single such pattern is indicated in each Figure.

In some embodiments, the edge of each of the through-holes at the front surface of the faceplate may be rounded with a radius that provides advantageous results. Each through-hole extends through the faceplate and forms an edge where it intersects with the front surface of the faceplate. An edge may refer to a sharp or rounded edge. In the case of a sharp edge, the edge refers to the region where two surfaces, e.g., a cylindrical through-hole surface and the front surface of the faceplate, intersect. In the case of a rounded edge, the intersecting surfaces may, in reality, not actually intersect since the round acts to terminate the surfaces before they contact each other. However, such rounded geometries are still referred to herein as “edges” despite the lack of an actual surface intersection. A sharp edge, as used herein, refers to an edge that does not have any deliberate rounding or radius, and the sharp edge may be created by two surfaces that intersect and have an internal angle less than 180 degrees, such as 90 degrees. It is to be understood, however, that some rounding of a sharp edge may be introduced which is not intended to be present, for example, over time, a sharp edge may be rounded by wear and tear from repeated processing and cleaning operations.

Using traditional machining processes, through-holes in faceplates generally have a sharp or non-radiused edge and such processes may result in burs or other sharp, uneven points. It has been discovered by the present inventors that through-holes with sharp edges may adversely affect semiconductor processing operations. For instance, hollow cathode discharge (HCD) is the sparking of a plasma around and inside a through-hole with a sharp edge or burr; HCD may also be caused by the plasma sheathes merging inside a through-hole that has a too large diameter. HCD may cause a local, high density plasma to form inside and around the through-hole which can cause more localized deposition at that location on the wafer which can lead to localized nonuniformity and wafer defects. The present inventors have discovered that this HCD effect may be reduced by rounding each through-hole edge with a radius of a sufficient size and/or by having the through-hole diameter less than a particular amount, such as the above-mentioned 0.02 inches which is small enough to prevent some plasma sheaths from merging inside the through-holes.

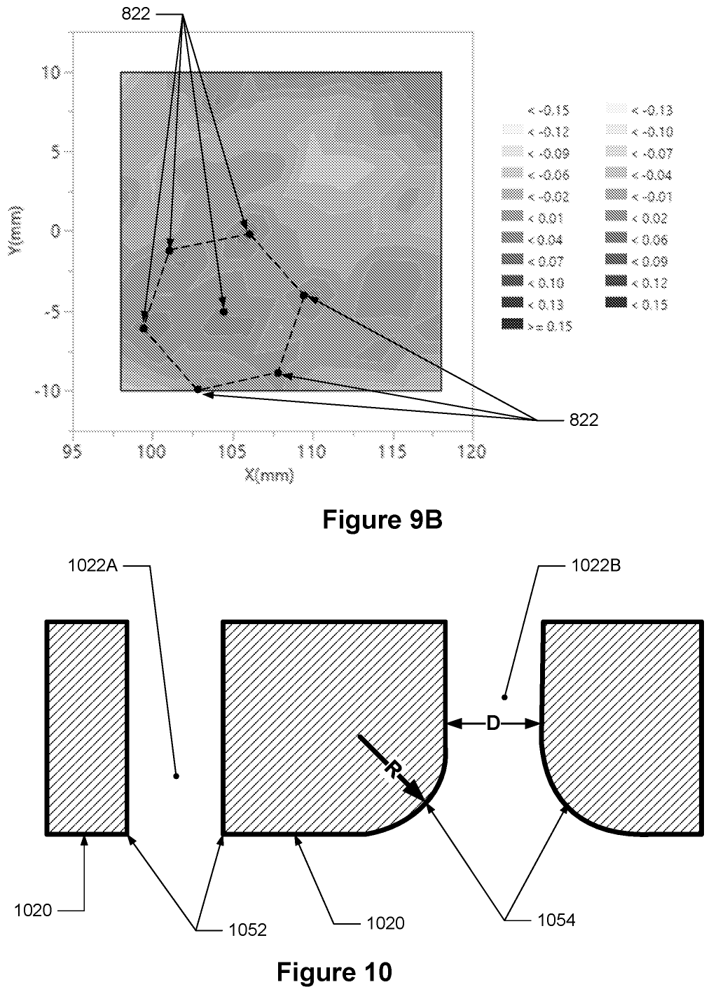

FIG. 10 depicts a magnified, partial cross-sectional view of two example through-holes of a faceplate. Here, the left through-hole 1022A forms a sharp edge 1052 with the front surface 1020 of the faceplate while the right through-hole 1022B forms a rounded edge 1054 having a radius R with the front surface 1020 of the faceplate. It has further been found by the present inventors that, in some embodiments, making the radius equal to, or substantially equal to (e.g., within ±10%, 25%, and 50%), the hole diameter prevents the occurrence of HCD. For example, it was found that using a through-hole diameter of 0.02 inches and a rounded edge with a radius of 0.02 inches prevented the occurrence of HCD, while using a through-hole diameter of 0.02 inches and a rounded edge with a radius of 0.005 inches did not reduce HCD occurrence. In FIG. 10, the radius R of edge 1054 of the through-hole 1022B may be considered substantially equal, e.g., within 10%, to the diameter D of the through-hole 1022B.

In some embodiments, the radius on each through-hole may be formed by electropolishing the faceplate. This electrochemical process involves dipping the metal faceplate in solution and applying voltage which preferentially reduces material from high points and sharp high points and therefore smooths out the sharp edges of the through-holes. Such rounding, including rounding the circumferential edges of 0.02 inch through-holes to a 0.02-inch radius is difficult to do with mechanical polishing, as such processes may actually generate more burrs.

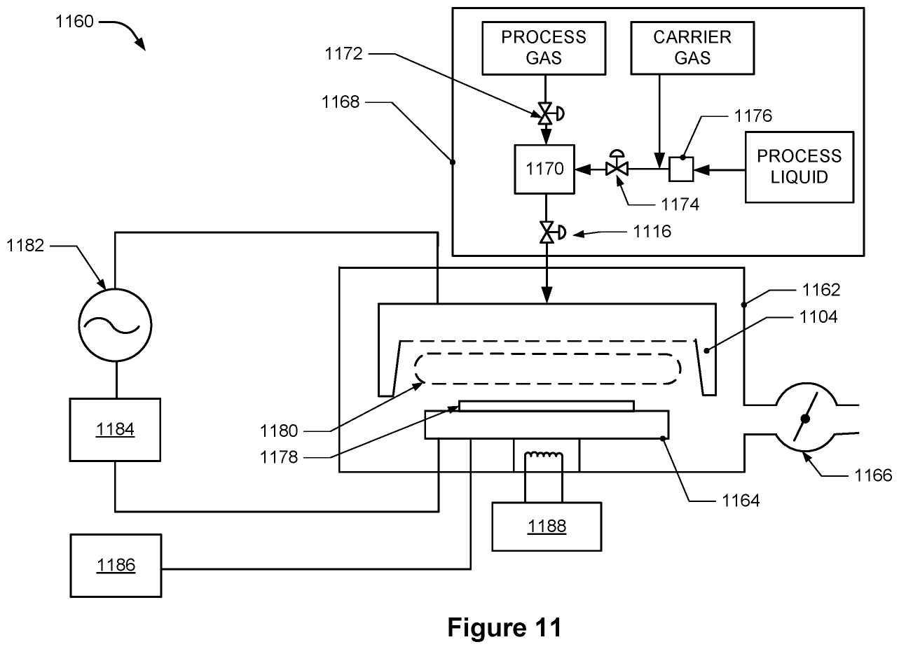

The showerhead described herein may be used in various semiconductor processing chambers and substrate processing apparatuses. FIG. 11 depicts a schematic of a substrate processing apparatus for depositing films on semiconductor substrates using any number of processes. The apparatus 1160 of FIG. 11 has a single processing chamber 1162 with a single substrate holder 1164 (e.g., a pedestal or an electrostatic chuck) in an interior volume which may be maintained under vacuum by vacuum pump 1166. Also fluidically coupled to the chamber for the delivery of (for example) film precursors, carrier and/or purge and/or process gases, secondary reactants, etc. is gas delivery system 1168 and showerhead 1104. The showerhead 1104 may be any of the showerheads described herein. Equipment for generating a plasma within the processing chamber is also shown in FIG. 11. The apparatus schematically illustrated in FIG. 11 is commonly for performing Atomic Layer Deposition (ALD), although it may be adapted for performing other film deposition operations such as conventional Chemical Vapor Deposition (CVD), particularly plasma enhanced CVD (PECVD).

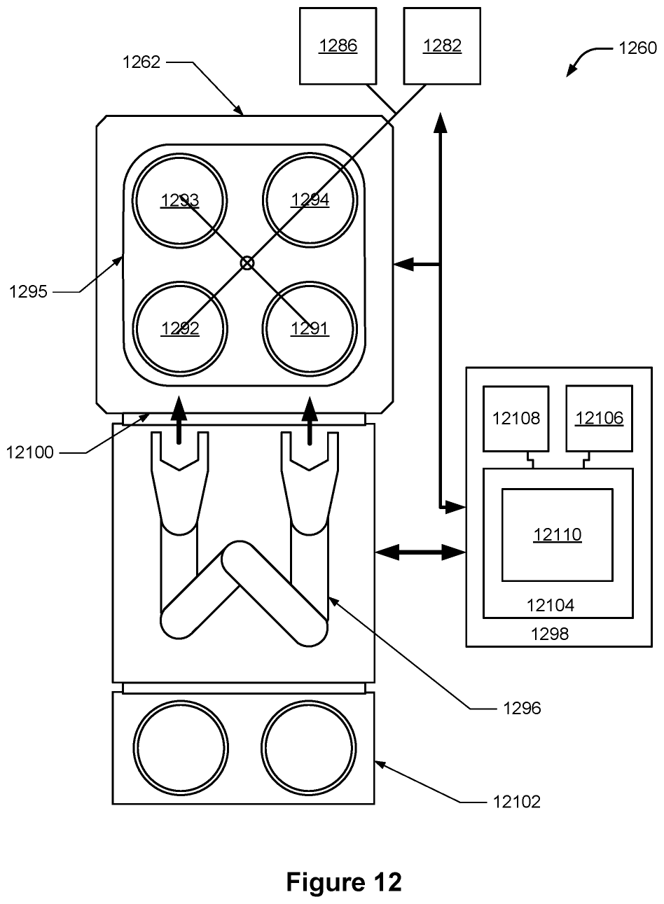

For simplicity, processing apparatus 1160 is depicted as a standalone process station having a process chamber body 1162 for maintaining a low-pressure environment. However, it will be appreciated that a plurality of process stations may be included in a common process tool environment—e.g., within a common reaction chamber—as described herein. For example, FIG. 12 depicts an implementation of a multi-station processing tool and is discussed in further detail below. Further, it will be appreciated that, in some implementations, one or more hardware parameters of processing apparatus 1160, including those discussed in detail herein, may be adjusted programmatically by one or more system controllers.

Process station 1162 fluidically communicates with gas delivery system 1168 for delivering process gases, which may include liquids and/or gases, to the showerhead 1104. Gas delivery system 1168 includes a mixing vessel 1170 for blending and/or conditioning process gases for delivery to showerhead 1104. One or more mixing vessel inlet valves 1172 and 1174 may control introduction of process gases to mixing vessel 1170.

Some reactants may be stored in liquid form prior to vaporization and subsequent to delivery to the process chamber 1162. The implementation of FIG. 11 includes a vaporization point 1176 for vaporizing liquid reactant to be supplied to mixing vessel 1170. In some implementations, vaporization point 1176 may be a heated liquid injection module. In some other implementations, vaporization point 1176 may be a heated vaporizer. In yet other implementations, vaporization point 1176 may be eliminated from the process station. In some implementations, a liquid flow controller (LFC) upstream of vaporization point 1176 may be provided for controlling a mass flow of liquid for vaporization and delivery to processing chamber 1162.

Showerhead 1104 distributes process gases and/or reactants (e.g., film precursors) toward substrate 1178 at the process station, the flow of which is controlled by one or more valves upstream from the showerhead (e.g., valves 1180, 1172, and 1174). In the implementation shown in FIG. 11, substrate 1178 is located beneath showerhead 1104, and is shown resting on a pedestal 1164. In some implementations with two or more stations, the gas delivery system 1168 includes valves or other flow control structures upstream from the showerhead, which can independently control the flow of process gases and/or reactants to each station such that gas may be flowed to one station but not another. Furthermore, the gas delivery system 1168 may be configured to independently control the process gases and/or reactants delivered to each station in a multi-station apparatus such that the gas composition provided to different stations is different; e.g., the partial pressure of a gas component may vary between stations at the same time.

A volume 1180 is located beneath showerhead 1104. In some implementations, the pedestal 1164 may be raised or lowered to expose substrate 1178 to volume 1180 and/or to vary a volume of volume 1180. Optionally, the pedestal 1164 may be lowered and/or raised during portions of the deposition process to modulate process pressure, reactant concentration, etc. within volume 1180.

In FIG. 11, showerhead 1104 and pedestal 1164 are electrically connected to an RF power supply 1182 and matching network 1184 for powering a plasma. In some implementations, the plasma energy may be controlled (e.g., via a system controller having appropriate machine-readable instructions and/or control logic) by controlling one or more of a process station pressure, a gas concentration, an RF source power, an RF source frequency, and a plasma power pulse timing. For example, RF power supply 1182 and matching network 1184 may be operated at any suitable power to form a plasma having a desired composition of radical species. Likewise, RF power supply 1182 may provide RF power of any suitable frequency and power. The apparatus 1160 may also include a DC power supply 1186 that is configured to provide a direct current to the pedestal 1164, which may be an ESC, in order to generate and provide an electrostatic clamping force to the ESC 1164 and the substrate 1178. The pedestal 1164 may also have one or more temperature control elements 1188 that are configured to heat and/or cool the substrate 1164.

In some implementations, the apparatus is controlled with appropriate hardware and/or appropriate machine-readable instructions in a system controller which may provide control instructions via a sequence of input/output control (IOC) instructions. In one example, the instructions for setting plasma conditions for plasma ignition or maintenance are provided in the form of a plasma activation recipe of a process recipe. In some cases, process recipes may be sequentially arranged, so that all instructions for a process are executed concurrently with that process. In some implementations, instructions for setting one or more plasma parameters may be included in a recipe preceding a plasma process. For example, a first recipe may include instructions for setting a flow rate of an inert (e.g., helium) and/or a reactant gas, instructions for setting a plasma generator to a power set point, and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure.

As described above, one or more process stations may be included in a multi-station substrate processing tool. FIG. 12 shows an example multi-station substrate processing apparatus. Various efficiencies may be achieved through the use of a multi-station processing apparatus like that shown in FIG. 12 with respect to equipment cost, operational expenses, as well as increased throughput. For instance, a single vacuum pump may be used to create a single high-vacuum environment for all four process stations by evacuating spent process gases, etc. for all four process stations. Depending on the implementation, each process station may have its own dedicated showerhead for gas delivery, but may share the same gas delivery system. Likewise, certain elements of the plasma generator equipment may be shared amongst process stations (e.g., power supplies), although depending on the implementation, certain aspects may be process station-specific (for example, if showerheads are used to apply plasma-generating electrical potentials). Once again, it is to be understood that such efficiencies may also be achieved to a greater or lesser extent by using more or fewer numbers of process stations per processing chamber such as 2, 3, 5, 6, 7, 8, 9, 10, 11, 12, 13, 14, 15, or 16, or more process stations per reaction chamber.

The substrate processing apparatus 1260 of FIG. 12 employs a single substrate processing chamber 1262 that contains multiple substrate process stations, each of which may be used to perform processing operations on a substrate held in a wafer holder, e.g., a pedestal or an ESC, at that process station. In this particular implementation, the multi-station substrate processing apparatus 1260 is shown having four process stations 1291, 1292, 1293, and 1294. Other similar multi-station processing apparatuses may have more or fewer processing stations depending on the implementation and, for instance, the desired level of parallel wafer processing, size/space constraints, cost constraints, etc. Also shown in FIG. 12 are a substrate handler robot 1296 and a controller 1298.

As shown in FIG. 12, the multi-station processing tool 1260 has a substrate loading port 12100, and a robot 1296 configured to move substrates from a cassette loaded through a pod 12102 through atmospheric port 12100, into the processing chamber 1262, and onto one of the four stations 1291, 1292, 1293, and 1294. The tool 1260 also has a wafer handling system 1295 for transferring wafers within processing chamber 1262. In some embodiments, wafer handling system 1295 may transfer wafers between various process stations and/or between a process station and a load lock. It will be appreciated that any suitable wafer handling system may be employed. Non-limiting examples include wafer carousels (as shown in FIG. 12) and wafer handling robots.

The depicted processing chamber 1262 shown in FIG. 12 provides four process stations, 1291, 1292, 1293, and 1294. The RF power is generated at an RF power system 1282 and distributed to each of the stations 1291, 1292, 1293, and 1294; similarly a DC power source 1286 is distributed to each of the station. The RF power system 1282 may include one or more RF power sources, e.g., a high frequency (HFRF) and a low frequency (LFRF) source, impedance matching modules, and filters. In certain implementations, the power source may be limited to only the high frequency or low frequency source. The distribution system of the RF power system may be symmetric about the reactor and may have high impedance. This symmetry and impedance result in approximately equal amounts of power being delivered to each station.

FIG. 12 also depicts an implementation of a system controller 1298 employed to control process conditions and hardware states of process tool 1260 and its process stations. System controller 1298 may include one or more memory devices 12104, one or more mass storage devices 12106, and one or more processors 12108. Processor 12108 may include one or more CPUs, ASICs, general-purpose computer(s) and/or specific purpose computer(s), one or more analog and/or digital input/output connection(s), one or more stepper motor controller board(s), etc.

The system controller 1298 may execute machine-readable system control instructions 12110 on processor 12108 the system control instructions 12110, in some implementations, loaded into memory device 12104 from mass storage device 12106. System control instructions 12110 may include instructions for controlling the timing, mixture of gaseous and liquid reactants, chamber and/or station pressure, chamber and/or station temperature, wafer temperature, target power levels, RF power levels, RF exposure time, DC power and duration to clamp a substrate, substrate pedestal, chuck, and/or susceptor position, plasma formation in each station (which, as discussed above, may include independent plasma formation in one or more stations), flow of gaseous and liquid reactants (which, as stated above, may include independent flow to one or more stations) and other parameters of a particular process performed by process tool 1260. These processes may include various types of processes including, but not limited to, processes related to deposition of film on substrates. System control instructions 1298 may be configured in any suitable way.

The electronics may be referred to as the “controller,” which may control various components or subparts of the system or systems. The controller, depending on the processing requirements and/or the type of system, may be programmed to control any of the processes disclosed herein, as well as various parameters affecting semiconductor processing, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The term “wafer,” as used herein, may refer to semiconductor wafers or substrates or other similar types of wafers or substrates. A wafer station, as the term is used herein, may refer to any location in a semiconductor processing tool in which a wafer may be placed during any of various wafer processing operations or wafer transfer operations. Wafer support is used herein to refer to any structure in a wafer station that is configured to receive and support a semiconductor wafer, e.g., a pedestal, an electrostatic chuck, a wafer support shelf, etc.

It is also to be understood that any use of ordinal indicators, e.g., (a), (b), (c), . . . , herein is for organizational purposes only, and is not intended to convey any particular sequence or importance to the items associated with each ordinal indicator. There may nonetheless be instances in which some items associated with ordinal indicators may inherently require a particular sequence, e.g., “(a) obtain information regarding X, (b) determine Y based on the information regarding X, and (c) obtain information regarding Z”; in this example, (a) would need to be performed (b) since (b) relies on information obtained in (a)-(c), however, could be performed before or after either of (a) and/or (b).

It is to be understood that use of the word “each,” such as in the phrase “for each <item> of the one or more <items>” or “of each <item>,” if used herein, should be understood to be inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, when a selected item may have one or more sub-items and a selection of one of those sub-items is made, it will be understood that in the case where the selected item has one and only one sub-item, selection of that one sub-item is inherent in the selection of the item itself.

It will also be understood that references to multiple controllers that are configured, in aggregate, to perform various functions are intended to encompass situations in which only one of the controllers is configured to perform all of the functions disclosed or discussed, as well as situations in which the various controllers each perform subportions of the functionality discussed.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

Unless the context of this disclosure clearly requires otherwise, words using the singular or plural number also generally include the plural or singular number respectively. When the word “or” is used in reference to a list of two or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein.

The term “substantially” herein, unless otherwise specified, means within 5% of the referenced value. For example, substantially perpendicular means within +/−5% of parallel. The term “substantially” may be used herein to indicate that while exactness of measurements and relationships may be intended, exactness is not always achieved or achievable because of manufacturing imperfections and tolerances. For instance, it may be intended to manufacture two separate features to have the same size (e.g., two holes), but because of various manufacturing imperfections, these features may be close to, but not exactly, the same size.

What is claimed is:

1. A showerhead comprising:
a faceplate having a front surface, a back surface, and a plurality of through-holes extending through the faceplate from the front surface to the back surface,
a gas inlet,
a plenum volume fluidically connected to the gas inlet within the showerhead and at least partially defined by the back surface, wherein the back surface includes a nonplanar region that:
extends around a center axis of the faceplate,
has an outer boundary and an inner boundary that are offset from each other along the center axis by a first distance, the outer boundary is closer to the gas inlet in a direction parallel to the center axis than the inner boundary, and the outer boundary is offset radially outwards from the inner boundary, and
has a nonplanar surface that spans between the inner boundary and the outer boundary.

2. The showerhead of claim 1, wherein the back surface further includes a circular planar region that is perpendicular to the center axis and has an outer circumferential edge defined by the inner boundary of the nonplanar region.

3. The showerhead of claim 1, wherein the nonplanar surface is a surface of revolution that:
is defined by a linear profile rotated about the center axis,
extends between the inner boundary and the outer boundary, and
is oriented at an oblique angle to the center axis.

4. The showerhead of claim 1, wherein the nonplanar surface is a conical frustum surface.

5. The showerhead of claim 1, wherein the nonplanar surface is a conical surface.

6. The showerhead of claim 1, wherein the nonplanar surface is a surface of revolution defined by a nonlinear profile rotated about the center axis and extending between the inner boundary and the outer boundary.

7. The showerhead of claim 1, wherein:
one or more first through-holes of the plurality of through-holes extends from the nonplanar region to the front surface, and each one or more through-hole has a first length,
one or more second through-holes of the plurality of through-holes extends from the nonplanar region to the front surface and are arranged farther from the center axis in a direction parallel to the center axis than the one or more first through-holes, and
the one or more second through-holes each have a second length that is longer than the first length of the one or more first through-holes.

8. The showerhead of claim 1, wherein:
each through-hole forms an edge with the front surface, and
each edge has a radius.

9. The showerhead of claim 8, wherein the radius of each edge and the diameter of each through-hole are substantially the same.

10. The showerhead of claim 8, wherein each through-hole has a diameter of between about 0.01 and 0.03 inches.

11. The showerhead of claim 8, wherein the radius is formed by electropolishing.

12. The showerhead of claim 8, wherein the radius is formed by machining and electropolishing.

13. The showerhead of claim 1, wherein:
the through-holes are arranged in a plurality of hexagonal patterns,
each hexagonal pattern has six exterior holes arranged around a center hole, and
the six exterior holes are equally spaced from each other and equally spaced from the center hole.

14. The showerhead of claim 13, wherein the distance between the six exterior holes and the center hole of each hexagonal pattern is between about 0.1 and 0.4 inches.

15. The showerhead of claim 1, wherein the outer boundary is larger in diameter than a semiconductor substrate diameter.

16. The showerhead of claim 15, wherein the outer boundary has a diameter between 7.5 inches and 13 inches.

17. The showerhead of claim 1, wherein the first distance is between 0.01 inches and 0.075 inches.

18. The showerhead of claim 1, wherein the inner boundary has a diameter of between about 0 inches and 8.5 inches.

19. The showerhead of claim 1, further comprising a back plate having the gas inlet and a first surface, wherein the plenum volume is further defined by the first surface.

20. The showerhead of claim 1, further comprising a baffle plate having a baffle plate outer diameter and positioned within the plenum volume.

21. The showerhead of claim 20, wherein the baffle plate outer diameter and a diameter of the inner boundary are substantially the same.

22. A faceplate for use in a processing chamber of a semiconductor processing apparatus, the faceplate comprising:
a front surface;
a back surface including a center point and a nonplanar region, wherein the nonplanar region:
extends around a center axis of the faceplate,
has an outer boundary and an inner boundary that are offset from each other along the center axis by a first distance, the inner boundary is closer to the center point in a direction parallel to the center axis than the outer boundary, and the outer boundary is offset radially outwards from the inner boundary, and
has a nonplanar surface that spans between the inner boundary and the outer boundary; and
a plurality of through-holes that extend through the faceplate from the front surface to the back surface, wherein each through-hole forms an edge with the front surface and the edge has a radius.

23. The faceplate of claim 22, wherein the nonplanar surface is a surface of revolution that:
is defined by a linear profile rotated about the center axis,
extends between the inner boundary and the outer boundary, and
is oriented at an oblique angle to the center axis.

24. The faceplate of claim 22, wherein:
the nonplanar region is a conical frustum surface, and
the back surface further includes a circular planar region that is perpendicular to the center axis and has an outer circumferential edge defined by the inner boundary of the nonplanar region.

25. The faceplate of claim 22, wherein the nonplanar region is a conical surface.

26. The faceplate of claim 22, wherein the nonplanar surface is a surface of revolution defined by a nonlinear profile rotated about the center axis and extending between the inner boundary and the outer boundary.
